(19) United States
(12) Patent Application Publication
(10) Pub. No.: US 2007/0139078 A1
(43) Pub. Date: Jun. 21, 2007

(54) PCML driver for LVDS receiver loads

(76) Inventors: George C. Tang, Cupertino, CA (US); Freeman Zhong, San Ramon, CA (US)

Correspondence Address: Pete Scott, Senior Corporate Counsel;LSI Logic Corporation, Legal Department - IP, MS D-106, 1621 Barber Lane, Milpitas, CA, 95035, US

(21) Appl. No.: 11/314,768

(22) Filed: Dec. 20, 2005

(51) Int. Cl. H03K 19/094

(52) U.S. Cl. 326/87

(57) ABSTRACT

The improved PCML communications driver corrects current loss and reduced voltage swing when driving an LVDS receiver load by reducing the value of the Rt1 resistors. By changing the value of the two Rt1 resistors from Rt1 to Rt1/2 (or lower), the full bias current can be restored and voltage swing is substantially improved. By making Rt1 a programmable resistor so Rt=Rt1/2 for DC bias calculation, Q2 bias current is increased back to IB, instead of IB/2.

### FIELD OF THE INVENTION

The present invention is generally related to signal drivers as used in the communications industry. More particularly, the present invention is related to the communications interface of a driver with a load. The present invention is also related to the interface of a PCML driver with an LVDS receiver load.

### BACKGROUND

Drivers are used in communications. PCML and LVDS are two different signal driver types. Because different circuits utilize different drivers for the transmitters and receivers, it is necessary to interface diverse driver types with varying loads. All drivers have different voltage swings and load end termination. Because there are so many types of communications drivers, there is a need for drivers that can interface with varying loads.

In the ideal case a PCML driver would be interfaced with a PCML receiver. Such an interface provides optimum voltage swings, reduced reflection and the best signaling. Because of the different types of drivers and receivers in use, it is now necessary to try to interface diverse drivers and receivers. The problem that the present inventor was interested in resolving is to interfacing a PCML driver with a LVDS receiver.

Referring to FIG. 1, labeled as “prior art”, what is illustrated is a typical full-swing PCML driver 110 interfaced with a typical load termination 120, such as a PCML receiver. The PCML driver has two transistors, Q1 and Q2, forming two separate branches, and a third biasing transistor Q3 with current labeled IB. Two resistors labeled Rt1 and of the same Ohm rating are connected between VDD1 and the emitter for transistors Q1 and Q2. The typical load is shown with two equally rated resistors labeled Rt2 are each connected to VDD2 and in parallel with Rt1 resistors associated with Q1 and Q2. The ideal load as depicted in FIG. 1 assumes the typical case where the value of Rt2 is equal to the value of Rt1.

Referring to FIG. 2, also labeled as “prior art”, is a simplified circuit 130 for the PCML driver circuit 110 in FIG. 1, which assumes the typical case where Rt1 (driver) equal Rt2 (load) and illustrates how voltage swing is analyzed. To determine the output swing of the typical case where all four resistors are of equal value, the circuit can be simplified so that only two transistors are shown, Q1 and Q2, and the four resistors can be shown as two resistors of equal value, Rt1/2. The output node Vd2 where voltage swing can be analyzed is located between the drain for Q2 and Rt1/2, which is the parallel value of Rt1 and Rt2 shown in FIG. 1. To determine the swing at the node Vd2, the node voltage is measured. The maximum single-ended swing at the node can be shown mathematically as follows:

$$\begin{matrix}Vswing = VOH - VOL \\ = V ( Q 2\_off ) - V ( Q2\_fullon ) \\ = VDD 1 - [ VDD 1 - 2 ( IB / 2 ) ( Rt 1 / 2 ) ] \\ = IB * Rt 1 / 2.\end{matrix}$$

The bias current IB is controlled by the constant current source and is shared by Q1 and Q2. The current through the resistors becomes IB. When Q2 is turned off, then all the current must be provided through Q1, and vis-à-vis.

When PCML driver is driving a PCML load, the bias current IB is provided from VDD1 and VDD2 through the resistors tied to each source. As shown in FIG. 3, labeled as “prior art”, where a LVDS load 220 is involved, the bias current produced by the driver circuit 210 is dropped in half because the load resistors are not tied to a power source (i.e., VDD2), the voltage swing is caused to be reduced in half. The Rt2 resistors are tied together, instead of being tied to a power source, thereby creating a virtual ground node, N_vg. Therefore, no bias current is flowing through Rt2, which causes IB to be reduced in half to IB/2. The reduction in bias current causes the voltage swing to also be reduced by about one-half. A smaller swing causes signals to be less effective because they are not able to be driven as far.

Referring to FIG. 4, labeled as “prior art”, a simplified circuit 230 showing voltage swing calculation analysis for a LVDS load is depicted. The circuit can no longer assume that Rt=Rt1/2 as was the case for a typical load. The maximum single-ended swing at node Vd2 can be shown mathematically as:

$$\begin{matrix}Vswing = VOH - VOL \\ = V ( Q 2\_off ) - V ( Q 2\_fullon ) \\ = VDD 1 - [ VDD 1 - 2 ( IB / 4 ) ( Rt 1 / 2 ) ] \\ = IB * Rt 1 / 4 ,\end{matrix}$$

which shows that the swing is dropped in half compared to the swing for a typical load.

Reduced bias current resulting in reduced voltage swing is a problem in communications where distance and signal clarity are important. Furthermore, the circuit is more susceptible to noise or reflection where the current has been lowered. What is needed is a solution that will improve voltage swing where PCML drivers are used to drive LVDS loads.

### SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings and abstract as a whole.

The improved PCML driver corrects current loss and reduced voltage swing by reducing the value of the Rt1 resistors.

By changing the value of the two Rt1 resistors from Rt1 to Rt1/2 (half), the full bias current can be restored and voltage swing is substantially improved.

By making Rt1 a programmable resistor so Rt=Rt1/2 for DC bias calculation, Q2 bias current is increased back to IB, instead of IB/2. Rt can also be programmed to have a value smaller than Rt1/2 to achieve even larger swing at the expense of consuming more power than the original PCML circuit. This can be done on an “as needed” basis.

### BRIEF DESCRIPTION OF THE DRAWINGS

The accompanying figures, in which like reference numerals refer to identical or functionally similar elements throughout the separate views and which are incorporated in and form part of the specification, further illustrate embodiments of the present invention.

FIG. 1, labeled as “prior art”, illustrates a circuit diagram for a typical full-swing PCML driver interfaced with a typical load termination, such as a PCML receiver;

FIG. 2, labeled as “prior art”, illustrates a circuit diagram for the PCML driver circuit in FIG. 1;

FIG. 3, labeled as “prior art”, illustrates a circuit diagram wherein a LVDS load is involved and wherein bias current produced by the driver circuit is dropped in half because the load resistors are not tied to a power source, and the voltage swing is caused to be reduced in half;

FIG. 4, labeled as “prior art”, illustrates a circuit diagram enabling the voltage swing calculation analysis for a LVDS load;

FIG. 5 illustrates a driver circuit diagram for a circuit driving LVDS load with changed value of two Rt1 resistors from Rt1 to Rt1/2 (or lower);

FIG. 6 illustrates a simplified circuit diagram supporting the voltage swing calculation analysis for a LVDS load; and

FIG. 7 illustrates a circuit diagram for an LVDS driver.

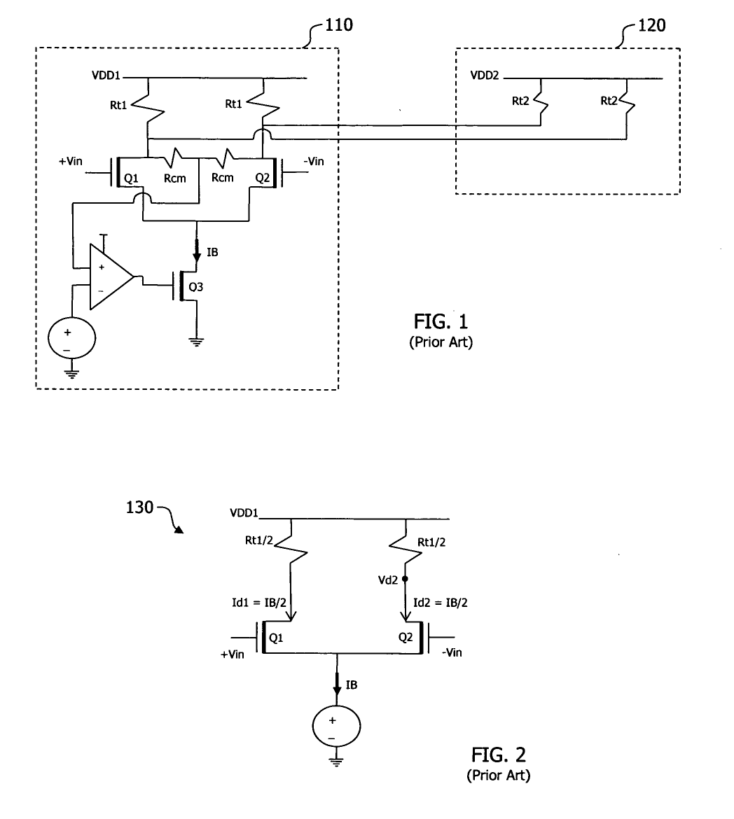

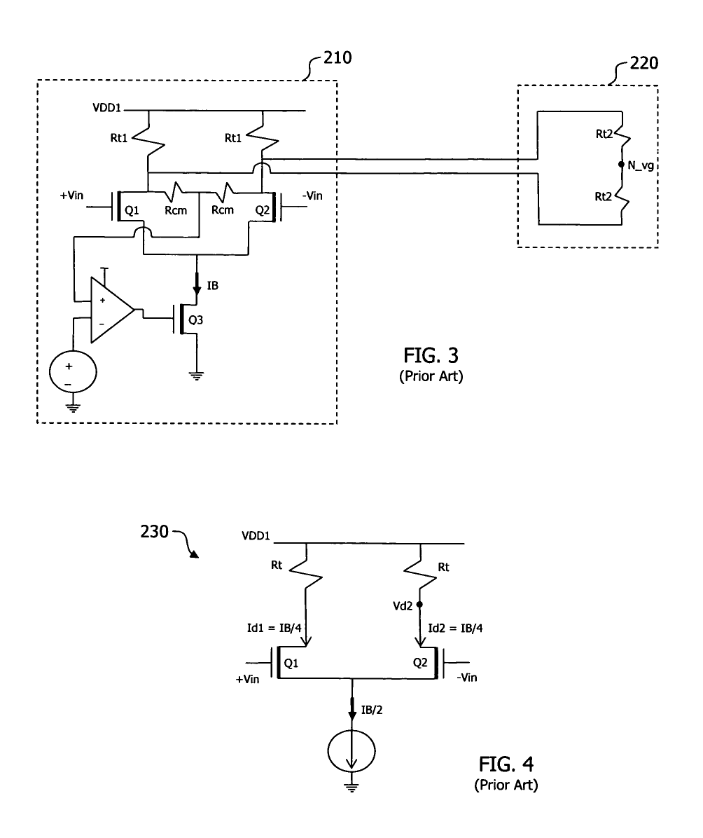

### DETAILED DESCRIPTION OF THE INVENTION

The particular values and configurations discussed in these non-limiting examples can be varied and are cited merely to illustrate embodiments of the present invention and are not intended to limit the scope thereof.

As stated in the background, the bias current is dropped in half where a LVDS load is driven by a PCML driver because the load resistors associated with the LVDS load are not tied to a power source (i.e., they are not tied to a VDD2), which causes the voltage swing to be reduced in half. Instead, the Rt2 resistors are tied together, creating a virtual ground node, N_vg. A smaller swing causes signals to be less effective because they are not able to be driven as far. A solution is now proposed that will correct current loss and reduce voltage swing where PCML drivers are used to drive LVDS loads. The improved PCML driver used for LVDS load can be designed to correct current loss and reduce voltage swing by reducing the value of the Rt1 resistors.

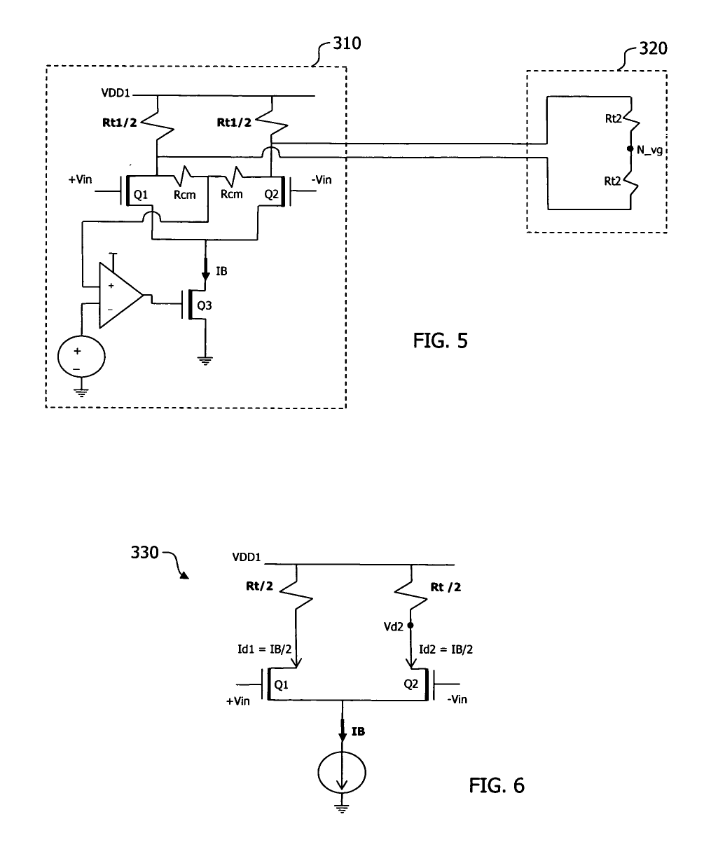

As shown in the driver circuit 310 driving LVDS load 320 illustrated in FIG. 5, by changing the value of the two Rt1 resistors from Rt1 to Rt1/2 (or lower), the full bias current can be restored and voltage swing is substantially improved. By making Rt1 a programmable resistor so Rt=Rt1/2 for DC bias calculation, Q2 bias current is increased back to IB/2, instead of IB/4.

Referring to FIG. 6, a simplified circuit 530 illustrates voltage swing calculation analysis for a LVDS load is shown. The circuit 530 shows that Rt=Rt1/2 for DC bias calculation so that Q2 bias current can be increased. The maximum single-ended swing at node Vd2 with the change of Rt1/2 can be shown mathematically as:
Vswing=2(IB/2)[(Rt1/2)//Rt2]=IB*Rt1/3.

This enables most of the swing lost due to the LVDS termination to be regained. An improvement to more than 50% swing, even if the swing is now closer to 66%, is a substantial improvement for communications applications.

Because PCML drivers share the bias current IB between VDD1 And VDD2, through Rt1 and Rt2 typically rated at 50 ohms, the common mode voltage will drop if PCML drivers are used to drive 100 ohm floating loads to replace LVDS drivers and the feedback loop of the bias network will reduce IB and reduce voltage swing. To correct this, Rt1 can be set to 25 ohms, which will maintain the same IB and enable most of the voltage swing to be regained. Setting Rt1=25 ohms does not violate the LVDS specification because LVDS loads do not have a fixed output impedance requirement. It can be appreciated that more swing can be achieved where Rt1 is reduced.

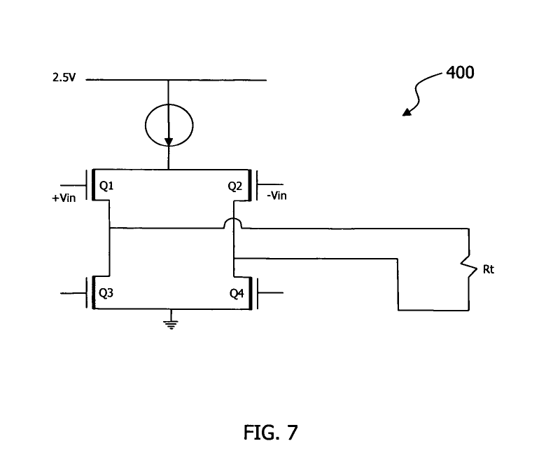

Referring to FIG. 7, an LVDS driver 400 is shown. The LVDS driver 400 is controlled by four transistors, Q1, Q2, Q3 and Q4. During basic operation, when the left side of the drivers output has to go high, then the transistor Q1 turns on to pull the output high while transistor Q3 turns off to enable Q1 to make the output to go high. The opposite effect occurs with Q2 and Q4. Resistance through the transistors is not fixed. Their resistance is dependent on several factors such as process variation, temperature and voltage. The output impedance can fluctuate (e.g., from 10 to 200 ohms) given different variables. When a driver is driving a transmission line (e.g., copper wire or board trace), it may present a load impedance mismatch with the receiver. When an impedance mismatch occurs, it can cause a reflection back toward the transmitter from the receiver. If the transmitter is properly terminated by using a 50 ohms resistor, then reflection is minimized. By lowering the resistance by half to 25 ohms, there is concern that reflection will be produced and interfere with the original signal transmitted from the transmitter to the receiver.

LVDS output not having fixed impedance can be accommodated by using a 25 ohm Rt1 instead of 50 ohms Rt1. Using a smaller resistance should not be a problem if the impedance mismatch along the transmission line being driven is within +/−30% of the specified characteristic impedance, Zo. With a 30% mismatch at the load, the reflected signal from the load to the transmitter then back to the load will be less than 5.5% for a very low loss line. But for a low loss line, large swing is not needed, so Rt1 can be programmed to be 50 ohms with reduced output swing. For higher loss lines, 25 ohms can be used and reflection should be less than 2%. Even if high signal attenuation is experienced with higher loss line scenarios, the larger voltage swing provided with the lower resistance value for Rt can compensate for signal loss.

The description as set forth is not intended to be exhaustive or to limit the scope of the invention. Many modifications and variations are possible in light of the above teaching without departing from the scope of the following claims. It is contemplated that the use of the present invention can involve components having different characteristics. It is intended that the scope of the present invention be defined by the claims appended hereto, giving full cognizance to equivalents in all respects.

1. An improved communications driver circuit correcting current loss and reducing voltage swing when connected to a communications receiver load, the circuit comprising two reduced value Rt1 resistors lowered in value from Rt1 to Rt1/2, wherein full bias current can be restored and voltage swing substantially improved after the reduction.

2. The driver circuit of claim 1, wherein said driver circuit represents a PCML driver circuit.

3. The driver circuit of claim 2 wherein Rt1 is a programmable resistor so Rt=Rt1/2 for DC bias calculation, wherein Q2 bias current is increased back to IB, instead of IB/2.

4. The driver circuit of claim 2, wherein said receiver load represents an LVDS receiver.

5. The improved PCML driver circuit of claim 5 wherein Rt1 is a programmable resistor so Rt=Rt1/2 for DC bias calculation, wherein Q2 bias current is increased back to IB, instead of IB/2.

6. The driver circuit of claim 1 wherein said receiver load represents an LVDS receiver.

7. The driver circuit of claim 6 wherein Rt1 is a programmable resistor so Rt=Rt1/2 for DC bias calculation, wherein Q2 bias current is increased back to IB, instead of IB/2.

8. The driver circuit of claim 6, wherein said driver circuit represents a PCML driver circuit.

9. The driver circuit of claim 8 wherein Rt1 is a programmable resistor so Rt=Rt1/2 for DC bias calculation, wherein Q2 bias current is increased back to IB, instead of IB/2.

10. The driver circuit of claim 1 wherein Rt1 is a programmable resistor so Rt=Rt1/2 for DC bias calculation, wherein Q2 bias current is increased back to IB, instead of IB/2.

11. The driver circuit of claim 10, wherein said driver circuit represents a PCML driver circuit.

12. The driver circuit of claim 11 wherein said receiver load represents an LVDS receiver.

13. The driver circuit of claim 10 wherein said receiver load represents an LVDS receiver.

14. The driver circuit of claim 13, wherein said driver circuit represents a PCML driver circuit.

15. An improved PCML driver circuit correcting current loss and reducing voltage swing when connected to a communications receiver load, the circuit comprising two reduced value Rt1 resistors lowered in value from Rt1 to Rt1/2, wherein full bias current can be restored and voltage swing substantially improved after the reduction.

16. The driver circuit of claim 15, wherein said receiver load represents an LVDS receiver.

17. The driver circuit of claim 16 wherein Rt1 is a programmable resistor so Rt=Rt1/2 for DC bias calculation, wherein Q2 bias current is increased back to IB, instead of IB/2.

18. The driver circuit of claim 15 wherein Rt1 is a programmable resistor so Rt=Rt1/2 for DC bias calculation, wherein Q2 bias current is increased back to IB, instead of IB/2.

19. The driver circuit of claim 18, wherein said receiver load represents an LVDS receiver.

20. An improved PCML driver circuit correcting current loss and reducing voltage swing when connected to a LVDS receiver, the circuit comprising two reduced value Rt1 resistors lowered in value from Rt1 to Rt1/2, wherein full bias current can be restored and voltage swing substantially improved after the reduction.

21. The driver circuit of claim 20 wherein Rt1 is a programmable resistor so Rt=Rt1/2 for DC bias calculation, wherein Q2 bias current is increased back to IB, instead of IB/2.
